(19) United States
(12) Patent Application Publication
(10) Pub. No.: US 2007/0224709 A1
(43) Pub. Date: Sep. 27, 2007

(54) PLASMA PROCESSING METHOD AND APPARATUS, CONTROL PROGRAM AND STORAGE MEDIUM

(75) Inventor: Masahiro OGASAWARA, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/689,840

(22) Filed: Mar. 22, 2007

Related U.S. Application Data
(60) Provisional application No. 60/788,104, filed on Apr. 3, 2006.

(30) Foreign Application Priority Data
Mar. 23, 2006 (JP) 2006-080312

(51) Int. Cl. H01L 21/00; G06F 19/00; C23F 1/00; H01L 21/306; H01L 21/302

(52) U.S. Cl. 438/5; 156/345.24; 438/689; 700/121; 156/345.28

(57) ABSTRACT

A plasma processing method for performing a plasma process by employing a plasma processing apparatus including a processing chamber for performing the plasma process on a target object, a mounting table for mounting thereon the target object in the processing chamber, a peripheral member disposed around a periphery of the mounting table, and a voltage application unit. The voltage application unit applies a voltage to the peripheral member based on an amount of abrasion of the peripheral member, a result of a pre-performed processing or a variation of an electric field formed over the peripheral member.

### FIELD OF THE INVENTION

The present invention relates to a plasma processing method and, more particularly, to a plasma processing method for performing a plasma process such as etching or the like on a target object, e.g., a semiconductor wafer, in a manufacturing process of various semiconductor devices.

### BACKGROUND OF THE INVENTION

In a manufacturing process of semiconductor devices, a plasma etching is repeatedly performed in order to form a fine circuit pattern on a target object, e.g., a semiconductor wafer. For example, the plasma etching is performed in such a manner that in a chamber of a plasma etching apparatus whose inside can be depressurized and evacuated, a high-frequency voltage is applied between electrodes facing each other to generate plasma, and a semiconductor wafer mounted on a mounting table is etched by the plasma. In this plasma etching process, a focus ring having a function of concentrating an etchant which is a plasma active species on a surface of the semiconductor wafer is installed at a periphery of the semiconductor wafer mounted on the mounting table, thereby allowing the etching process to be performed.

As for the conventional plasma process using the focus ring, to prevent an abnormal discharge (arcking) between the surface of the semiconductor wafer and the focus ring from being generated by a potential difference occurred between the semiconductor wafer and the focus ring during etching, there has been proposed a plasma processing apparatus configured to be able to control the potential of the focus ring by applying a DC voltage to a lower electrode. (see, for example, International Publication No. WO 03/009363 (claims etc.))

However, the focus ring is consumables, and the surface thereof is slowly worn away by the plasma while repeating the plasma etching, whereby the shape thereof gradually changes. Therefore, there is a problem in that the decrease in thickness accompanied with the abrasion of the focus ring has an adverse effect on the etching shape at a peripheral portion of the semiconductor wafer. To be specific, in case of forming a hole by etching, the hole is obliquely formed at the peripheral portion of the semiconductor wafer, whereby the control of the etching shape becomes difficult. Further, the in-surface uniformity of the etching shape of the semiconductor wafer cannot be obtained due to the difference in the etching shape occurring between a central portion and a peripheral portion of the semiconductor wafer. To prevent the non-uniformity in the etching shape, the focus ring should be replaced before it can have a severe influence on the etching shape. Due to this, a replacement cycle of the focus ring becomes short, which results in one of the causes of reducing the component lifetime.

Further, as a method for predicting an amount of abrasion of the focus ring, there has been proposed a multivariate analysis method for analyzing the data obtained by measuring numerous electrical data varying depending on the amount of abrasion of the focus ring with the lapse of time (see, for example, Japanese Patent Laid-open Application No. 2002-25982 (claims etc.)). However, this method predicts merely the amount of abrasion, and does not consider prolonging the component lifetime of the focus ring.

As a result of investigating the causes that the etching shape varies according to the abrasion of the focus ring, it is confirmed that as the thickness of the focus ring becomes thin by the abrasion thereof, the state of the plasma sheath formed over the focus ring changes, whereby an incident angle of ions falling on the semiconductor wafer changes, thus resulting in an influence on the etching shape at the peripheral portion of the semiconductor wafer. As a countermeasure therefor, it is possible to make in advance the thickness of the focus ring thick in a range without affecting the etching shape. However, by this method, it is inevitable that the etching shape changes gradually as the focus ring is abraded, and thus, this method does not provide a fundamental solution.

### SUMMARY OF THE INVENTION

It is, therefore, an object of the present invention to provide a plasma processing method capable of significantly reducing an adverse influence on a processing result such as an etching shape caused by the abrasion of a focus ring and at the same time prolonging the life span of the focus ring.

In accordance with a first aspect of the present invention, there is provided a plasma processing method for performing a plasma process by employing a plasma processing apparatus, the plasma processing apparatus including a processing chamber for performing the plasma process on a target object, a mounting table for mounting thereon the target object in the processing chamber, a peripheral member disposed around a periphery of the mounting table, and a voltage application unit, wherein the voltage application unit applies a voltage to the peripheral member based on an amount of abrasion of the peripheral member.

In the first aspect, it is preferable that the amount of abrasion of the peripheral member is estimated based on a cumulative usage time of the peripheral member.

Further, it is preferable that the voltage applied to the peripheral member is determined in advance based on a relationship between the amount of abrasion of the peripheral member and variation of an electric field formed over the peripheral member.

In accordance with a second aspect of the present invention, there is provided a plasma processing method for performing a plasma process by employing a plasma processing apparatus, the plasma processing apparatus including a processing chamber for performing the plasma process on a target object, a mounting table for mounting thereon the target object in the processing chamber, a peripheral member disposed around a periphery of the mounting table, and a voltage application unit, wherein the voltage application unit applies a voltage to the peripheral member based on a result of a pre-performed plasma process.

In accordance with a third aspect of the present invention, there is provided a plasma processing method for performing a plasma process by employing a plasma processing apparatus, the plasma processing apparatus including a processing chamber for performing the plasma process on a target object, a mounting table for mounting thereon the target object in the processing chamber, a peripheral member disposed around a periphery of the mounting table, a voltage application unit, and a monitoring device for monitoring a state of an electric field formed over the peripheral member, wherein the monitoring device detects a variation of the electric field formed over the peripheral member, and the voltage application unit applies a voltage to the peripheral member based on the detection result.

In any one of the first to third aspects, it is preferable that the voltage is applied to the peripheral member to correct the discrepancy between an electric field formed over the target object and the electric field formed over the peripheral member.

Further, it is preferable that the voltage is applied to the peripheral member such that a thickness of a plasma sheath formed over the peripheral member is thicker than that of a plasma sheath formed over the target object.

Further, it is preferable that the voltage is applied to the peripheral member to suppress a difference between results processed in a central portion and a peripheral portion of the target object.

Further, it is preferable that the plasma process is a plasma etching and the voltage is applied to the peripheral member to suppress a difference between etching shapes in a central portion and a peripheral portion of the target object. In this case, it is preferable that the peripheral member is a focus ring.

Further, in any one of the first to third aspects, it is preferable that the voltage applied to the peripheral member is controlled to be in the range from about 10 V to 500 V. Furthermore, the voltage applied to the peripheral member may be set at a ground potential.

In accordance with a fourth aspect of the present invention, there is provided a control program executable on a computer for controlling, when executed, a plasma processing apparatus to perform the plasma etching method claimed in any one of the first to third aspects.

In accordance with a fifth aspect of the present invention, there is provided a computer readable storage medium for storing a control program executable on a computer, wherein the control program controls, when executed, a plasma processing apparatus to perform the plasma etching method in any one of the first to third aspects.

In accordance with a sixth aspect of the present invention, there is provided a plasma processing apparatus comprising:

a processing chamber for performing a plasma process on a target object;

a mounting table for mounting thereon the target object in the processing chamber;

a peripheral member disposed around a periphery of the mounting table;

a voltage application unit for applying a voltage to the peripheral member; and

a controller for controlling the plasma etching method in the first aspect or the second aspect to be performed in the processing chamber.

In accordance with a seventh aspect of the present invention, there is provided a plasma processing apparatus comprising:

a processing chamber for performing a plasma process on a target object;

a mounting table for mounting thereon the target object in the processing chamber;

a peripheral member disposed around a periphery of the mounting table;

a voltage application unit for applying a voltage to the peripheral member;

a monitoring device for monitoring a state of an electric field formed over the peripheral member; and

a controller for controlling the plasma etching method in the third aspect to be performed in the processing chamber.

In accordance with the present invention, since the voltage application unit applies a specified voltage to the peripheral member based on the amount of abrasion of the peripheral member, the pre-performed plasma processing result, or the detection result of the variation of the electric field formed over the peripheral member to thereby perform the plasma process, e.g., the plasma processing results such as the in-surface uniformity of the etching shape or the like can be improved. Accordingly, the plasma processing method of the present invention can be advantageously employed to improve the ratio of the product to the materials of the semiconductor device and the reliability, thereby making it possible to cope with the miniaturization of the semiconductor device.

Further, even when the peripheral member is somewhat abraded, an adverse effect on the plasma processing results can be significantly reduced by applying the voltage thereto, whereby the component lifetime of the peripheral member can be substantially prolonged. Accordingly, the downtime of the apparatus and the component cost accompanied with the component replacement can be reduced and further the plasma processing efficiency can be improved.

### BRIEF DESCRIPTION OF THE DRAWINGS

The above and other objects and features of the present invention will become apparent from the following description of embodiments given in conjunction with the accompanying drawings, in which:

FIG. 1 is a schematic diagram of a plasma etching apparatus adapted for implementing a method of the present invention;

FIG. 2 schematically shows a state of a plasma sheath in case of using a focus ring which is not abraded;

FIG. 3 schematically describes a state of a plasma sheath in case of using an abraded focus ring;

FIG. 4 schematically shows a state of a plasma sheath in case of applying a voltage to an abraded focus ring;

FIG. 5 is a flow chart for illustrating an exemplary voltage application sequence in the plasma process of a first embodiment;

FIG. 6 is a table used in the plasma process of the first embodiment;

FIG. 7 is a flow chart for illustrating an exemplary voltage application sequence in the plasma process of a second embodiment;

FIG. 8 is a table used in the plasma process of the second embodiment; and

FIG. 9 schematically shows the plasma process of a third embodiment.

### DETAILED DESCRIPTION OF THE EMBODIMENTS

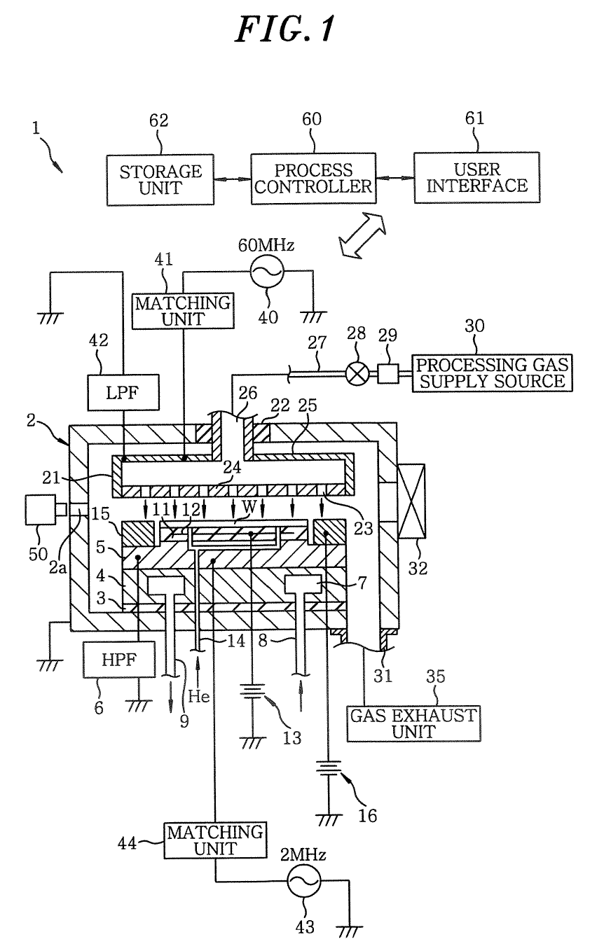

Hereinafter, embodiments of the present invention will be described in detail with reference to the accompanying drawings so that they can be readily implemented by those skilled in the art. FIG. 1 shows a schematic configuration of an exemplary plasma etching apparatus adapted for implementing a method of the present invention. The plasma etching apparatus 1 is of a capacitively coupled parallel plate type etching apparatus having upper and lower electrode plates placed to face each other in parallel, that are connected to high-frequency power supplies, respectively.

The plasma etching apparatus 1 includes a cylindrical chamber 2, for example, made of surface-alumited aluminum (anodized), wherein the chamber 2 is grounded. Disposed on a bottom portion of the chamber 2 is a substantially cylindrical susceptor support 4 for mounting thereon a target object, e.g., a semiconductor wafer (hereinafter, referred to as a “wafer”) W via an insulating plate 3 such as ceramic or the like. Further, installed on the susceptor support 4 is a susceptor 5 adapted to serve as a lower electrode. Connected to the susceptor 5 is a high pass filter (HPF) 6.

A temperature control medium container 7 is provided within the susceptor support 4. A temperature control medium is introduced into the temperature control medium container 7 via an inlet line 8 and circulated therein in such a manner that the temperature of the susceptor 5 can be controlled at a desired level.

The susceptor 5 is of a disk shape with a protruded central uppermost portion. Installed on the central uppermost portion of the susceptor 5 is an electrostatic chuck 11 shaped substantially the same as the wafer W. The electrostatic chuck 11 is formed by interposing an electrode 12 in an insulating material, and electrostatically adsorbs the wafer W by a Coulomb force generated by, e.g., a DC voltage of 1.5 kV supplied from a DC power supply 13 connected to the electrode 12.

Further, formed through the insulating plate 3, the susceptor support 4, the susceptor 5 and the electrostatic chuck 11 is a gas channel 14 for supplying a heat transfer medium, e.g., a He gas or the like, to a backside of the wafer W serving as a target object at a specific pressure. Heat is transferred between the susceptor 5 and the wafer W through the heat transfer medium, so that the wafer W is maintained at a specific temperature.

A ring-shaped focus ring 15, which is a peripheral member, is disposed on an upper peripheral portion of the susceptor 5 to surround the wafer W mounted on the electrostatic chuck 11. The focus ring 15 is made of an insulating material such as ceramic, quartz, or the like, and serves to improve the etching uniformity. Furthermore, a DC power supply 16 is connected to the focus ring 15 such that a DC voltage ranging from 10 V to 500 V can be applied thereto.

Otherwise, instead of connecting the DC power supply 16 to the focus ring 15, the focus ring 15 may be set at a ground potential by grounding it.

Further, installed above the susceptor 5 to face thereto in parallel is an upper electrode 21. The upper electrode 21 is supported within an upper portion of chamber 2 via an insulating member 22. Further, the upper electrode 21 includes an electrode plate 24, which is made of, e.g., quartz, facing towards the susceptor 5 and provided with a plurality of injection openings 23, and an electrode support 25, which is made of a conductive material, e.g., surface-alumited aluminum, for supporting the electrode plate 24. Further, the distance between the susceptor 5 and the upper electrode 21 is made to be adjustable.

Formed at a center of the electrode support 25 of the upper electrode 21 is a gas inlet opening 26 which is in turn connected to a gas supply line 27. And, the gas supply line 27 is connected to a processing gas supply source 30 via a valve 28 and a mass flow controller 29, through which an etching gas for plasma etching is supplied thereto from the processing gas supply source 30. Although FIG. 1 representatively shows only one processing gas supply source 30, the plasma processing apparatus may be provided with a plurality of processing gas supplying sources 30 and configured to supply, e.g., a halogen-based etching gas such as CF₄, CHF₃, Cl₂, HBr or the like, O₂, and a gas such as a rare gas, or the like into the chamber 2 by independently controlling flow rates thereof.

Connected to a bottom portion of the chamber 2 is a gas exhaust line 31, which in turn is coupled to a gas exhaust unit 35. The gas exhaust unit 35 is provided with a vacuum pump such as a turbo molecular pump or the like, and is configured to vacuum pump the inside of the chamber 2 down to a specific depressurized atmosphere, e.g., a specific vacuum pressure of 1 Pa or less. Further, installed on a sidewall of the chamber 2 is a gate valve 32. The wafer W is transferred between the chamber 2 and a load lock chamber adjacent thereto (not shown) while the gate valve 32 is opened.

A first high-frequency power supply 40 is connected to the upper electrode 21 by a feeder line via a matching unit 41. Further, a low pass filter (LPF) 42 is connected to the upper electrode 21. The first high-frequency power supply 40 has a frequency ranging from 50 MHz to 150 MHz. By applying a high frequency power in such a range, high density plasma in a desired dissociation state can be generated in the chamber 2, which makes it possible to execute the plasma process under a low pressure condition. The frequency of the first high-frequency power supply 40 preferably ranges from 50 to 80 MHz, and typically, is employed to have 60 MHz or near 60 MHz, as shown in FIG. 1.

A second high-frequency power supply 43 is connected to the susceptor 5 serving as the lower electrode by a feeder line via a matching unit 44. The second high-frequency power supply 43 has a frequency ranging from several hundred KHz to several tens MHz. By applying a power having a frequency in such a range, a proper ionic action can be facilitated without causing any damage on the wafer W. The frequency of the second frequency power supply 43 is employed to have, e.g., 2 MHz as shown in FIG. 1.

A transmission window 2a is formed at a location on a sidewall of the chamber 2 substantially corresponding to the height of the plasma sheath formed by plasma generated in the chamber 2. Further, a monitor 50 serving as a sheath state detection unit is installed at an outside of the transmission window 2a. The monitor 50 includes, e.g., a CCD camera or the like mounted thereon and is configured to monitor the state of the plasma sheath through the transmission window 2a during etching in the plasma etching apparatus 1.

Further, each component of the plasma etching apparatus 1 is connected to and controlled by a process controller 60 with a CPU. The process controller 60 is connected to a user interface 61 including a keyboard with which a process manager executes command input manipulation in order to manage the plasma etching apparatus 1, a display which visualizes and displays an operation status of the plasma etching apparatus 1, and the like.

Moreover, also connected to the process controller 60 is a storage unit 62 for storing therein recipes which record control programs (software), processing condition data and the like to be used in realizing various processes performed in the plasma etching apparatus 1 under the control of the process controller 60.

Further, if necessary, a necessary recipe is retrieved from the storage unit 62 by an instruction from the user interface 61 and executed by the process controller 60, whereby desired processing in the plasma etching apparatus 1 is performed under the control of the processing controller 60. For example, based on the amount of abrasion of the focus ring 15 or the variation of the plasma sheath formed over the focus ring 15 detected by the monitor 50, the process controller 60 decides a DC voltage to be applied to the focus ring 15, as will be described below. Moreover, it is possible to use the recipes such as the control programs, the processing condition data and the like stored in a computer readable storage medium, e.g., a CD-ROM, a hard disc, a flexible disc, a flash memory or the like, or to use the recipes on-line by transmitting it from other devices, e.g., via a dedicated line whenever necessary.

Next, a process for etching a wafer W made of single crystalline silicon by employing the plasma etching apparatus 1 with the above-described configuration will be schematically explained. First, the gate valve 32 is opened and then the wafer W having a specific mask layer (not shown) formed thereon, is conveyed into the chamber 2 from the load lock chamber (not shown) to be mounted on the electrostatic chuck 11. And then, by supplying a DC voltage from the DC power supply 13 to the electrostatic chuck 11, the wafer W is adsorbed thereto electrostatically.

Then, the gate valve 32 is closed and the chamber 2 is vacuum evacuated to a specific vacuum level by the gas exhaust unit 35. After that, the valve 28 is opened, and a specific processing gas for an etching target is supplied from the processing gas supply source 30 into a hollow portion of the upper electrode 21 via the processing gas supply line 27 and the gas inlet opening 26 while controlling a flow rate of the processing gas to a specific value by the mass flow controller 29. Then, the processing gas is discharged uniformly towards the wafer W as indicated by arrows in FIG. 1 via the injection openings 23 of the electrode plate 24.

In this plasma process, while maintaining the inner pressure of the chamber 2 at a specific pressure level and controlling the temperature of the susceptor 5 to a specific temperature level, by supplying high frequency powers to the upper electrode 21 and the susceptor 5 serving as the lower electrode from the first and the second high frequency power supplies 40 and 43, respectively, the plasma gas is converted into plasma to thereby perform etching of the wafer W. At this time, as will be described below, based on the amount of abrasion of the focus ring 15, the result of detecting the variation of the electric field formed over the focus ring 15, or the result of the pre-performed plasma process (e.g., the etching shape), a specific DC voltage is supplied to the focus ring 15 from the DC power supply 16 to thereby correct the displacement of the plasma sheath formed by plasma generated in the chamber 2, so that an incidence of ions falling on the wafer W can be controlled to be uniform. Accordingly, the in-surface uniformity of the etching shape of the wafer W can be obtained.

When the etching is completed, the high frequency powers from the first and the second high-frequency power supplies 40 and 43, the voltage from the DC power supply 16, and the processing gas from the processing gas supply 30 are stopped being supplied. Thereafter, the gate valve 32 is opened to convey out of the processed wafer W to the outside of the chamber 2. In this way, the plasma etching process on one wafer W is completed.

Next, the principle of the plasma processing method of the present invention will be now explained. In this connection, FIGS. 2 to 4 respectively show enlarged cross sectional views illustrating the proximity of the focus ring 15 in a state where plasma P is excited within the chamber 2, respectively. First, FIG. 2 shows a state of a plasma sheath Ps in case of using the focus ring 15 which is not abraded (e.g., a new one just after the replacement). In this state, the surfaces of the wafer W and the focus ring 15 are formed on a substantially same plane.

Herein, the thickness t₁ or t₂ of the plasma sheath Ps, i.e. a distance between the plasma P and the surface of its adjacent solid (e.g., the wafer W or the focus ring 15) can be represented by the following formula. Further, in this formula, t refers to either t₁ or t₂.

t∝(1/Ne)^{1/2}×V^{3/4}

Herein, Ne indicates a plasma density, and V indicates a voltage of the susceptor 5 represented by the following formula:

V∝(P)^{1/2}/S

Herein, P indicates an RF power supplied to the susceptor 5, and S indicates a surface area of the wafer W or the focus ring 15.

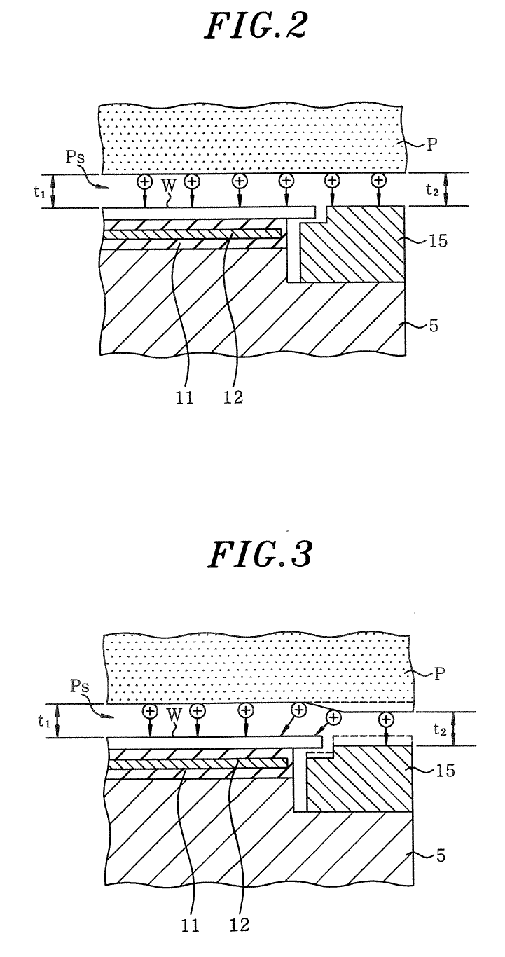

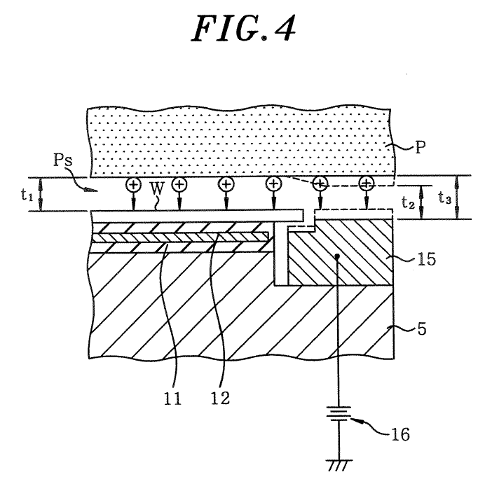

Further, the thickness t₁ of the plasma sheath Ps formed over the wafer W and the thickness t₂ of the plasma sheath Ps formed over the focus ring 15 derived from the above formula are substantially the same. In this state, as shown in FIG. 2, the etchant such as an ion or the like, which is a plasma active species, (herein, indicated by a plus sign and also applied to FIGS. 3 and 4), is substantially vertically incident on the surface of the wafer W or the focus ring 15, whereby the etching can be uniformly performed in the surface of the wafer W.

Next, FIG. 3 shows a state of the focus ring 15 abraded by using for a certain period of time. As shown in FIG. 3, the focus ring 15 is worn away and thinner by etching, and thus, the surface thereof is lower than that of the wafer W in its level. Therefore, one end of the plasma P formed over the focus ring 15 is lower than the central portion thereof indicated by a dashed line. That is, although the thickness t₁ of the plasma sheath Ps formed over the wafer W and the thickness t₂ of the plasma sheath Ps formed over the focus ring 15 are the same, the plasma sheath Ps is formed to be tilted between their two regions, resulting in occurring deformation. Herein, a surface position of the focus ring 15 before abrasion thereof is depicted by a dashed line for reference in FIG. 3. (This is also applied to FIG. 4)

Furthermore, if the deformation shown in FIG. 3 occurs in the plasma sheath Ps, an incident angle of the etchant on a part of the plasma sheath where the deformation occurs is shifted. Therefore, the etchant to be supposed to originally fall on the focus ring 15 are obliquely incident upon the peripheral portion of the wafer W. It is regarded that the shift of the incident angle of the etchant due to the shape change of the plasma sheath Ps results in a change of the etching shape at the peripheral portion of the wafer W.

FIG. 4 shows a state where a specific voltage (for example, 100 V) is applied from the DC power voltage 16 to the focus ring 15 whose thickness is thinner by abrasion. That is, by applying the voltage to the focus ring 15 to thereby change an electric field formed over the focus ring 15, the thickness t₂ of the plasma sheath Ps can be increased to t₃. To do this, the deformation of the plasma sheath Ps can be corrected, and therefore, it is possible to form the lower portion of the plasma P over the wafer W and the focus ring 15 on a substantially same plane. Further, as shown in FIG. 4, since the etchant such as an ion, which is a plasma active species, in the plasma P, can fall approximately vertically on the surface of the wafer W, it is possible to prevent the distortion of the etching shape at the peripheral portion of the wafer W. In this case, the voltage applied to the focus ring 15 from the DC power supply 16 is preferably controlled to be in the range from 10 V to 500 V. Furthermore, by changing the electric field formed over the focus ring 15 to improve the deformation of the plasma sheath Ps, the focus ring 15 may be preferably grounded to be set at a ground potential.

As described above, since the thickness of the plasma sheath Ps formed over the focus ring 15 can be adjusted by applying a specific pressure to the focus ring 15, the accuracy of the etching shape can be improved, thus enhancing the in-surface uniformity of the etching shape of the wafer W. Further, even when the focus ring 15 is somewhat abraded, it can be continuously used without having an influence on the etching shape. As a result, the component lifetime of the focus ring 15 is substantially prolonged, thereby reducing the downtime of the etching apparatus 1 and component cost accompanied with the component replacement.

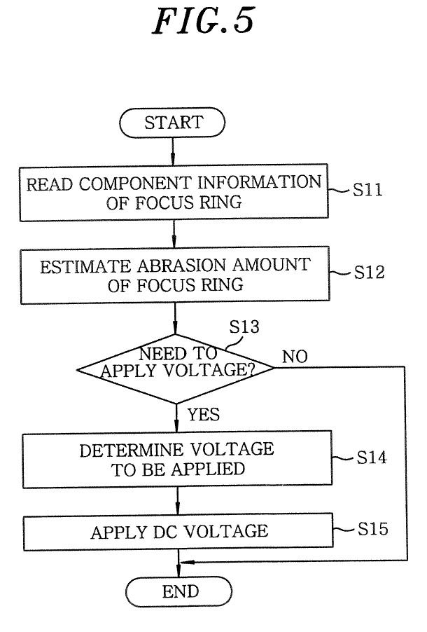

Further, FIG. 5 is a flow chart illustrating an exemplary processing sequence performed when the voltage is applied to the focus ring 15 in the plasma processing method of first embodiment of the present invention. In this embodiment, FIG. 5 represents a processing sequence in which the amount of abrasion of the focus ring 15 is first estimated; whether to apply a voltage to the focus ring 15 from the DC power supply 16 or not is determined on the basis of the estimated amount of abrasion; and then, in case of applying a voltage thereto, the voltage level is decided. The processing sequence of FIG. 5 can be properly carried out during a series of the processes performed using the plasma etching apparatus 1.

As shown in FIG. 5, in step S11, component information on the focus ring 15 stored in the storage unit 62 is read by the process controller 60. Otherwise, the component information on the focus ring 15 may be directly input by the process manager through the user interface 61. The component information includes, for example, a replacement date and time of the focus ring 15 and a cumulative operation time of the plasma etching apparatus 1 after the replacement date and time. Then, based on the read component information, the amount of abrasion of the focus ring 15 is estimated in step S12.

Since the amount of abrasion of the focus ring 15 is proportional to the usage time of the focus ring 15, it can be empirically derived from the usage time easily. Therefore, for example, by preparing a table, which is not shown, relating the amount of abrasion of the focus ring 15 and the usage time thereof, the process controller 60 compares the component information with the table to simply estimate the amount of abrasion of the focus ring 15. Otherwise, without estimation of the amount of abrasion by the component information, it is possible to directly measure and obtain the amount of abrasion of the focus ring 15. In this case, the processes in steps S11 and S12 may be omitted.

Next, in step S13, based on the amount of abrasion of the focus ring 15 obtained in step S12, it is determined whether it is necessary to apply a DC voltage to the focus ring 15 from the DC power supply 16 or not. If the focus ring 15 is being abraded, it is determined that the voltage needs to be applied thereto (Yes), while the voltage does not need to be applied thereto (No) if the focus ring 15 is little abraded (e.g., a new one).

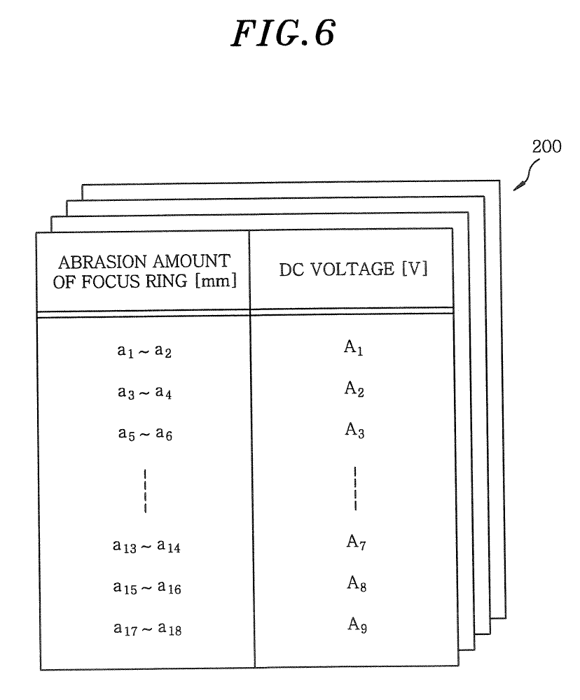

If it is determined that the voltage needs to be applied thereto (Yes) in step S13, the voltage level to be applied thereto is decided in step S14. At this time, a table 200 shown in FIG. 6 which relates the amount of abrasion of the focus ring 15 with the voltage level to be applied from the DC power supply 16 can be used. The table 200 is obtained in advance by investigating the influence of the amount of abrasion of the focus ring 15 on the plasma sheath Ps by experimentally applying a voltage to the focus ring 15 having a variety of amounts of abrasion, and stored in the storage unit 62. The process controller 60 reads the table 200 from the storage unit 62 and then compares it with the amount of abrasion of the focus ring 15 derived in step S12 (e.g., a₁ [mm]). Thus, the voltage level to be applied to the focus ring 15 (i.e. A₁[V]) is correspondingly determined. Further, in step S15, the determined DC voltage is applied to the focus ring 15 from the DC power supply 16.

In contrast, if it is determined that the voltage does not need to be applied thereto (No) in step S13, the plasma etching is performed without applying the voltage to the focus ring 15 from the DC power supply 16, whereby the processes in steps S14 and S15 are omitted.

It is preferable that the processing sequence shown in FIG. 5 is performed in case of processing a first one wafer W belonging to a certain lot. In this case, as for a second and later wafer in the same lot, the voltage is not applied thereto on the basis of the determination of step S13, otherwise the specified voltage determined in step S14 is applied thereto, thereby repeatedly performing the plasma etching process thereto. At that time, the ON/OFF of the DC power supply 16 can be performed by the process controller 60, for example, in a manner interlocked with the ON/OFF of the first high-frequency power supply 40 and the second high-frequency power supply 43 of the plasma etching apparatus 1 (the supply and stop of the high frequency power). In contrast, the processing sequence shown in FIG. 5 can be performed on every wafer W.

As described in steps S11 to S15 of FIG. 5, by estimating the amount of abrasion of the focus ring 15 from the usage time thereof and then determining the voltage to be applied to the focus ring 15 based on the corresponding amount of abrasion, the thickness t₂ of the plasma sheath Ps formed over the focus ring 15 can be adjusted. In this manner, it is possible to correct the shift of the ion incident angle at the peripheral portion of the wafer W caused by the displacement of the plasma sheath Ps. Therefore, the in-surface uniformity of the etching shape of the wafer is improved, whereby the ratio of the product to the materials of the semiconductor device can be enhanced. Further, even when the focus ring 15 is somewhat abraded, it can be continuously used by controlling the voltage level applied thereto without having an influence on the etching shape resulted from the plasma process. Accordingly, the replacement frequency of the focus ring 15 can be reduced, thus making it possible to reduce the downtime of the etching apparatus 1 and the component cost accompanied with the replacement.

In the table 200 shown in FIG. 6, there is shown a relationship between the amount of abrasion of the focus ring 15 and the DC voltage to be applied to the focus ring 15. However, it is also possible to use a table directly relating the usage time of the focus ring 15 with the DC voltage level to be applied thereto. In this case, although the process of estimating the amount of abrasion of the focus ring 15 in step S12 becomes unnecessary, it is requisite to estimate in advance the amount of abrasion of the focus ring 15 since determination of whether to apply the DC voltage to the focus ring 15 or not and the voltage to be applied are experimentally obtained from its relation to the amount of abrasion of the focus ring 15.

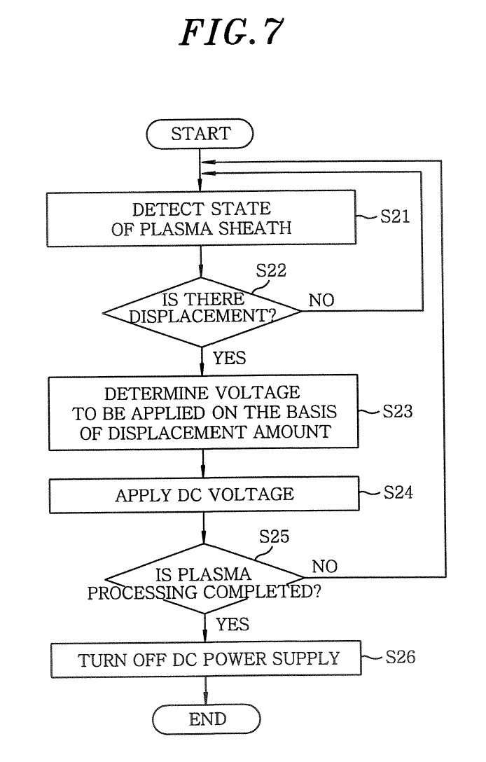

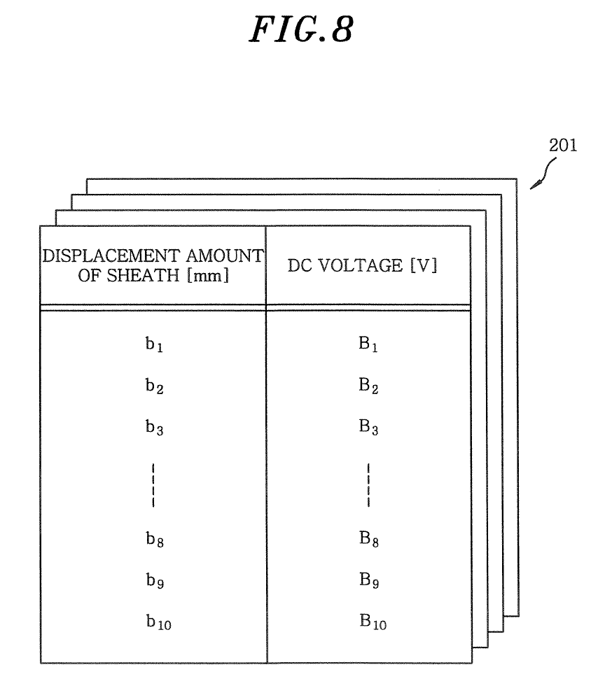

FIG. 7 is a flow chart illustrating an exemplary processing sequence performed when the voltage is applied to the focus ring 15 in the plasma processing method of a second embodiment of the present invention. The first embodiment determines the voltage to be applied by using the amount of abrasion of the focus ring 15 based on the well-known principle that the displacement of the plasma sheath Ps occurs due to the consumption of the focus ring 15. In contrast, this embodiment directly detects the displacement of the plasma sheath Ps of the plasma P, and applies a voltage to the focus ring 15 based on the displacement amount (the degree of the displacement). The processing sequence of FIG. 7 can be properly carried out during a series of the processes performed using the plasma etching apparatus 1.

As shown in FIG. 7, in step S21, the monitor 50 detects the state of the plasma sheath Ps of the plasma P generated within the chamber 2. Since the variation of the plasma sheath Ps formed over the focus ring 15 (i.e. the end portion of the plasma sheath Ps) is problematic from the point of view of achieving the uniformity in the plasma process, it is preferable to employ the monitor 50 capable of monitoring the end portion of the plasma P.

In this embodiment, the monitor 50 photographs the plasma sheath Ps of the end portion of the plasma P, and image data therefor is delivered to the process controller 60. The process controller 60 performs the image analysis based on the image data delivered from the monitor 50. Then, the displacement of the end portion of the plasma sheath Ps is, for example, evaluated and displayed on the display of the user interface 61 in a real-time. Next, in step S22, based on the result of the image analysis, the process controller 60 determines whether there is a displacement of the end portion of the plasma sheath Ps or not.

In step S22, if it is determined that there is a displacement of the end portion of the plasma sheath Ps (Yes), the process controller 60 refers to, e.g., a table 201 shown in FIG. 8 which is stored in advance in the storage medium 62. And then, based on the displacement of the plasma sheath Ps (e.g., b₃ [mm]), the voltage level (i.e. B₃ [V]) to be applied to the focus ring 15 from the DC power supply 16 is determined (step S23). The table 201 used herein represents the corresponding relationship between the displacement of the end portion of the plasma sheath Ps and the applied voltage required to correct the displacement, which are empirically obtained in advance.

Further, based on the determination of step S23, the specified voltage (e.g., B₃[V]) from the DC power supply 16 is applied to the focus ring 15 in following step S24. By applying the voltage to the focus ring 15 in this way, the thickness t₂ of the plasma sheath Ps formed over the focus ring 15 can be adjusted to a desired thickness. As a result, it is possible to correct the shift of the ion incident angle at the peripheral portion of the wafer W caused by the shape variation of the plasma sheath Ps. Accordingly, the in-surface uniformity of the etching shape of the wafer is improved, and therefore, the ratio of the product to the materials of the semiconductor device can be enhanced. Further, even when the focus ring 15 is somewhat abraded, it can be continuously used by controlling the voltage level applied thereto without having an influence on the etching shape. Therefore, the replacement frequency of the focus ring 15 can be reduced, thereby making it possible to reduce the downtime of the etching apparatus 1 and the component cost accompanied with the replacement.

Next, in step S25, the process controller 60 determines whether or not the plasma process is completed. For example, if the first and the second high-frequency power supplies 40 and 43 are turned on, it is determined that the plasma process is not completed (No), whereas if they are turned off, it is determined that the plasma process is completed (Yes). Further, if it is determined that the plasma process is completed (Yes) in step S25, the DC power supply 16 is turned off in step S26.

Meanwhile, if it is determined that there is no displacement of the end portion of the plasma sheath Ps (No) in step S22, a control process returns to step S21, where the detection of the position of the end portion of the plasma sheath Ps is performed again.

Likewise, if it is determined that the plasma process is not completed (No) in step S25, a control process returns to step S21, where the detection of the position of the end portion of the plasma sheath Ps is performed again. As described above, while the plasma process is performed in the plasma etching apparatus 1 (i.e., while the plasma P is excited), the processing sequence shown in FIG. 7 is repeatedly performed. During performing the plasma process, if there occurs a displacement of the plasma sheath Ps, an appropriate voltage level from the DC power supply 16 is applied to the focus ring 15 to adjust the shape of the plasma sheath Ps, whereby the control to prevent the adverse influence on the etching shape is performed.

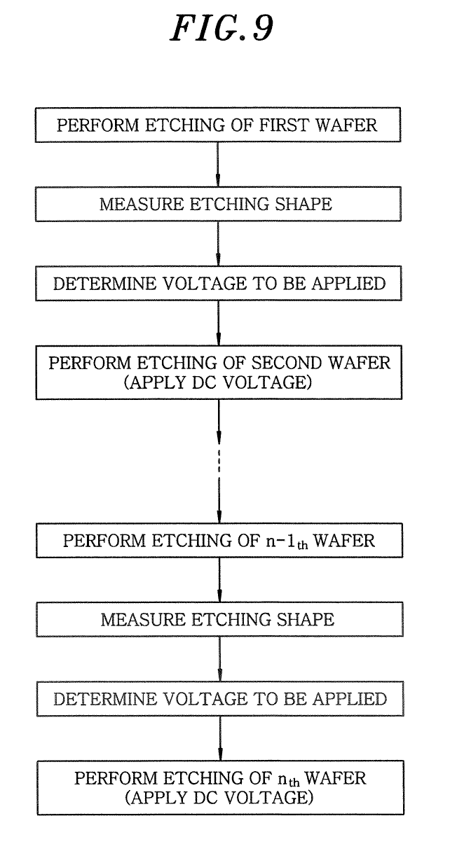

In the following, FIG. 9 is a flow chart illustrating an exemplary processing sequence in the plasma processing method in accordance with a third embodiment of the present invention. In this embodiment, a voltage is applied to the focus ring 15, if necessary, on the basis of the etching shape resulted from the plasma etching process.

First, the plasma etching is performed on a first wafer W by the above-described process using the plasma etching apparatus 1. Thereafter, the etching shape (e.g., a sidewall angle of a hole) of the first wafer W is measured. As mentioned above, if the deformation of the plasma sheath Ps occurs due to the abrasion of the focus ring 15 and therefore an incident angle of the etchant such as an ion is shifted (see, FIG. 3), the holes or the like is obliquely formed, e.g., at the peripheral portion of the wafer W. Therefore, for example, by measuring the sidewall angle of the hole with respect to a direction perpendicular to the surface of the wafer W using an electron microscope picture or the like, it is estimated that there exists a displacement (deformation) of the plasma sheath Ps.

Further, if it is estimated that there exists a displacement of the plasma sheath Ps based on the etching shape, as described in FIG. 9, the voltage to be applied to the focus ring 15 is determined depending on the extent of the shape. At this time, the relationship between the variation of the etching shape such as the holes or the like and the voltage to be applied to the focus ring 15 to improve the variation may be empirically determined in advance.

Furthermore, after determining the voltage to be applied, the determined voltage is applied to the focus ring 15, and the plasma etching is then performed on a second wafer W. In the plasma etching process on the second wafer W, since the voltage resulted from the plasma etching process on the first wafer W is applied to the focus ring 15 to correct the deformation of the plasma sheath Ps, the in-surface uniformity of the etching shape of the wafer W can be improved. Further, it is needless to say that a voltage does not have to be applied to the focus ring 15 if there is no problem in the etching shape of the first wafer W.

In this way, when the plasma etching is sequentially performed on a second, a third, . . . , an (n−1)^{th}, and an n^{th} wafer W, the voltage level to be applied to the focus ring 15 is determined by using the result of the pre-performed plasma etching process as feedback. Then, by applying the specified voltage to the focus ring 15 in the following process, the plasma etching process with the in-surface uniformity of the etching shape can be performed. In this connection, measuring the result of the plasma etching (etching shape) and determining the voltage to be applied may be performed on every wafer W or every several wafers. For example, in FIG. 9, the plasma etching process on the second wafer W and the nₜₕ wafer W is performed by applying the voltage to the focus ring 15, whereas the plasma etching process on the (n−1)^{th} wafer W is performed without applying the voltage to the focus ring 15.

As described above, in accordance with the third embodiment, by determining the voltage to be applied to the focus ring 15 in the following etching process based on the result of the etching, the shift of the ion incident angle at the peripheral portion of the wafer W caused by the displacement of the plasma sheath Ps is corrected. Thereby, the in-surface uniformity of the etching shape of the wafer can be improved, thus making it possible to improve the production yield of the semiconductor device. Further, even when the focus ring 15 is somewhat abraded, the influence on the etching shape can be avoided by controlling the voltage level applied thereto. Accordingly, the replacement frequency of the focus ring 15 can be reduced, thereby making it possible to reduce the downtime of the etching apparatus 1 and the component cost accompanied with the replacement.

Although the embodiments have been described above, the present invention is not limited thereto and various modifications may be made.

For example, though the above embodiments have been described with respect to the capacitively coupled parallel plate type etching apparatus having the upper electrode 21 and the susceptor 5 serving as the lower electrode to each of which a high frequency power is supplied, a plasma etching apparatus, e.g., wherein a high frequency power is supplied only to a lower electrode may be employed. Further, regardless of the shape of the plasma etching apparatus, e.g., various plasma etching apparatuses such as an inductively coupled plasma etching apparatus, a microwave plasma etching apparatus or the like can be used.

Furthermore, although the above embodiments have been described with respect to the case of improving the in-surface uniformity of the etching shape of the wafer W in the plasma etching process, the processing is not limited to the etching, and the present invention may be applied to any processor capable of improving the process result by applying a voltage to a peripheral member (e.g., a clamp ring) disposed around a periphery of a wafer W, for example, a film forming apparatus or the like.

While the invention has been shown and described with respect to the embodiments, it will be understood by those skilled in the art that various changes and modifications may be made without departing from the scope of the invention as defined in the following claims.

What is claimed is:

1. A plasma processing method for performing a plasma process by employing a plasma processing apparatus, the plasma processing apparatus including a processing chamber for performing the plasma process on a target object, a mounting table for mounting thereon the target object in the processing chamber, a peripheral member disposed around a periphery of the mounting table, and a voltage application unit,
wherein the voltage application unit applies a voltage to the peripheral member based on an amount of abrasion of the peripheral member.

2. The plasma processing method of claim 1, wherein the amount of abrasion of the peripheral member is estimated based on a cumulative usage time of the peripheral member.

3. The plasma processing method of claim 1, wherein the voltage applied to the peripheral member is determined in advance based on a relationship between the amount of abrasion of the peripheral member and variation of an electric field formed over the peripheral member.

4. A plasma processing method for performing a plasma process by employing a plasma processing apparatus, the plasma processing apparatus including a processing chamber for performing the plasma process on a target object, a mounting table for mounting thereon the target object in the processing chamber, a peripheral member disposed around a periphery of the mounting table, and a voltage application unit,
wherein the voltage application unit applies a voltage to the peripheral member based on a result of a pre-performed plasma process.

5. A plasma processing method for performing a plasma process by employing a plasma processing apparatus, the plasma processing apparatus including a processing chamber for performing the plasma process on a target object, a mounting table for mounting thereon the target object in the processing chamber, a peripheral member disposed around a periphery of the mounting table, a voltage application unit, and a monitoring device for monitoring a state of an electric field formed over the peripheral member,
wherein the monitoring device detects a variation of the electric field formed over the peripheral member, and the voltage application unit applies a voltage to the peripheral member based on the detection result.

6. The plasma processing method of any one of claims 1, 4 and 5, wherein the voltage is applied to the peripheral member to correct the discrepancy between an electric field formed over the target object and the electric field formed over the peripheral member.

7. The plasma processing method of any one of claims 1, 4 and 5, wherein the voltage is applied to the peripheral member such that a thickness of a plasma sheath formed over the peripheral member is thicker than that of a plasma sheath formed over the target object.

8. The plasma processing method of any one of claims 1, 4 and 5, wherein the voltage is applied to the peripheral member to suppress a difference between results processed in a central portion and a peripheral portion of the target object.

9. The plasma processing method of any one of claims 1, 4 and 5, wherein the plasma process is a plasma etching and the voltage is applied to the peripheral member to suppress a difference between etching shapes in a central portion and a peripheral portion of the target object.

10. The plasma processing method of claim 9, wherein the peripheral member is a focus ring.

11. The plasma processing method of any one of claims 1, 4 and 5, wherein the voltage applied to the peripheral member is controlled to be in the range from about 10 V to 500 V.

12. The plasma processing method of any one of claims 1, 4 and 5, wherein the voltage applied to the peripheral member is set at a ground potential.

13. A control program executable on a computer for controlling, when executed, a plasma processing apparatus to perform the plasma etching method claimed in any one of claims 1, 4 and 5.

14. A computer readable storage medium for storing a control program executable on a computer, wherein the control program controls, when executed, a plasma processing apparatus to perform the plasma etching method claimed in any one of claims 1, 4 and 5.

15. A plasma processing apparatus comprising:
a processing chamber for performing a plasma process on a target object;
a mounting table for mounting thereon the target object in the processing chamber;
a peripheral member disposed around a periphery of the mounting table;
a voltage application unit for applying a voltage to the peripheral member; and
a controller for controlling the plasma etching method claimed in claim 1 or 4 to be performed in the processing chamber.

16. A plasma processing apparatus comprising:
a processing chamber for performing a plasma process on a target object;
a mounting table for mounting thereon the target object in the processing chamber;
a peripheral member disposed around a periphery of the mounting table;
a voltage application unit for applying a voltage to the peripheral member;
a monitoring device for monitoring a state of an electric field formed over the peripheral member; and
a controller for controlling the plasma etching method claimed in claim 5 to be performed in the processing chamber.
